(19) United States
(12) Patent Application Publication
(10) Pub. No.: US 2026/0282509 A1
(43) Pub. Date: Sep. 17, 2026

(54) METHODS FOR FORMING SOURCE/DRAIN REGIONS OF CFETS

(71) Applicant: Taiwan Semiconductor Manufacturing Co., Ltd., Hsinchu (TW)

(72) Inventors: Yu-Hsien Chiang, Hsinchu (TW); Szu-Hua Chen, Tainan City (TW); Ku-Feng Yang, Baoshan Township (TW); Szuya Liao, Zhubei (TW)

(21) Appl. No.: 19/244,119

(22) Filed: Jun. 20, 2025

Related U.S. Application Data
(60) Provisional application No. 63/771,888, filed on Mar. 14, 2025.

(51) Int. Cl. H10D 84/01; H10D 30/01; H10D 62/00

(52) U.S. Cl. CPC H10D 84/017; H10D 30/019; H10D 62/021

(57) ABSTRACT

A method includes forming a multilayer stack comprising a first semiconductor nanostructure and a second semiconductor nanostructure over the first semiconductor nanostructure, forming a dummy gate stack over the multilayer stack, etching the multilayer stack to form a source/drain recess, forming a sacrificial region at a bottom of the source/drain recess, and performing a selective deposition process to form a dielectric liner. The dielectric liner is selectively deposited on a sidewall of the multilayer stack, and a top surface of the sacrificial region is exposed to the source/drain recess. The method further includes removing the sacrificial region, forming a lower source/drain region in the source/drain recess and electrically connected to the first semiconductor nanostructure, removing the dielectric liner to reveal the second semiconductor nanostructure, and forming an upper source/drain region to electrically connect to the second semiconductor nanostructure.

### PRIORITY CLAIM AND CROSS-REFERENCE

This application claims the benefit of the following provisionally filed U.S. Patent Application: Application No. 63/771,888, filed on Mar. 14, 2025, and entitled “CFET Process,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 17 are views of intermediate stages in the formation of CFETs in accordance with some embodiments.

FIG. 18 illustrates a flow chart for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) and the method of forming the same are provided. In accordance with some embodiments, in the formation of source/drain regions of CFETs, a source/drain recess is formed, and a sacrificial region is formed at the bottom of the source/drain recess. The sacrificial region may be a single-layer region comprising elemental carbon or a carbon-containing compound. A dielectric liner is then formed selectively, and extends into the source/drain recess. The dielectric liner is not formed on the top of the sacrificial region due to the selective formation process. Accordingly, the sacrificial region may be removed, and a source/drain region is formed in the space left by the removed sacrificial region. Accordingly, by forming the dielectric liner selectively, a plurality of etching processes related to the formation of the sacrificial region are avoided.

The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

It is appreciated that while Gate-All-Around (GAA) transistors (such as nanostructure-FETs) are discussed as examples, the concept of the present disclosure can also be applied to the formation of other types of transistors such as planar transistors, Fin Field-Effect Transistors (FinFETs), or the like. Throughout the description, the terms “FET” and “transistor” are used interchangeably.

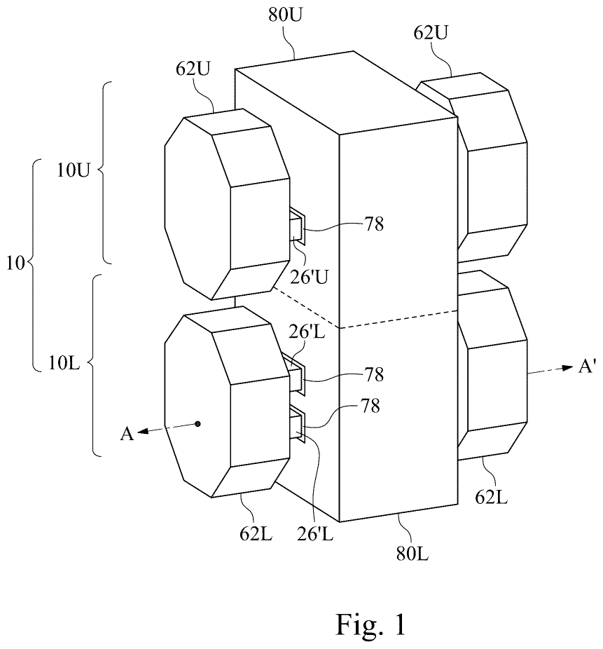

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Subsequent figures may refer to these reference cross-sections for clarity.

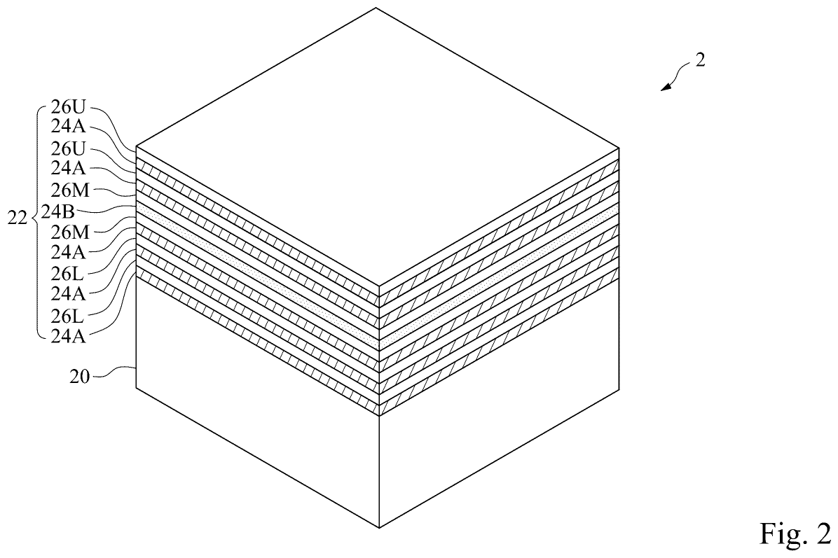

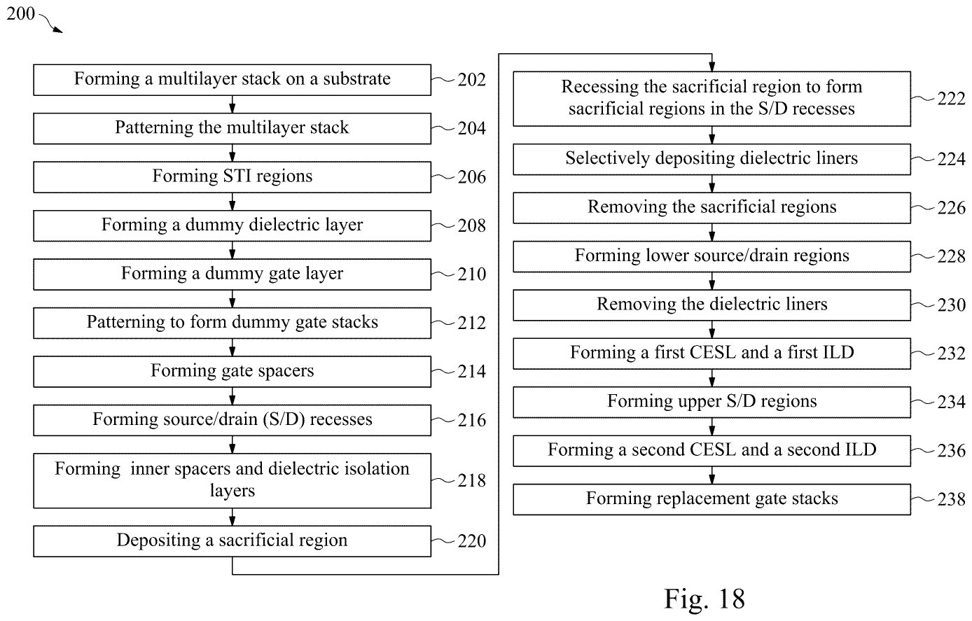

FIGS. 2-17 illustrate the cross-sectional views of intermediate stages in the formation of CFETs (as schematically represented in FIG. 1) in accordance with some embodiments. The corresponding processes are also reflected schematically in the process flow 200 as shown in FIG. 18. In subsequent discussion, unless specified otherwise, the figures having illustrate the vertical cross-sectional views along a similar cross-section as vertical reference cross-section A-A′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor; or the like, or combinations thereof.

A multilayer stack 22 is formed over the substrate 20. The respective process is illustrated as process 202 in the process flow 200 as shown in FIG. 18. The multilayer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively. The multilayer stack 22 may also include semiconductor nanostructures 26M, which may comprise silicon, and are used to define boundaries of the lower nanostructure-FETs and the upper nanostructure-FETs.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example as shown in FIG. 2, the multilayer stack 22 includes one lower semiconductor layer 26L and one upper semiconductor layer 26U. It should be appreciated that the multilayer stack 22 may include any number of the dummy semiconductor layers 24A and the semiconductor layers 26U and 26L. Accordingly, the illustrated one semiconductor layer 26L and one semiconductor layer 26U may also represent a plurality of semiconductor layers 26L and 26U, and are referred to in plural forms. Each layer of the multilayer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

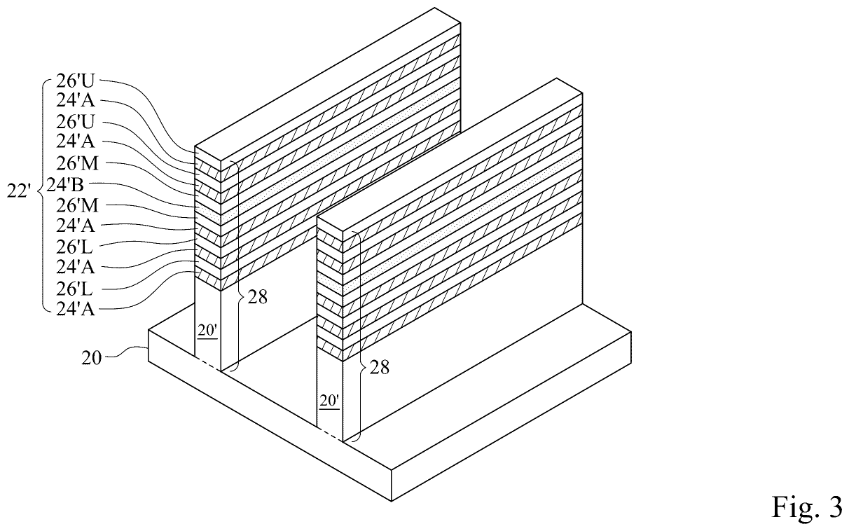

In FIG. 3, multilayer stack 22 and substrate 20 are patterned to form semiconductor strips 28. The respective process is illustrated as process 204 in the process flow 200 as shown in FIG. 18. Each of semiconductor strips 28 includes semiconductor strip 20′ (the portions of the original substrate 20) and multilayer stack 22′, which is the remaining portion of multilayer stack 22. The remaining portions 22′ of multilayers stack 22 are referred to as nanostructures hereinafter, which are referred to using the corresponding reference number followed by a “′” sign. Accordingly, multilayer stack 22′ includes dummy nanostructures 24′A, dummy nanostructures 24′B, lower semiconductor nanostructures 26′L, middle semiconductor nanostructures 26′M, and upper semiconductor nanostructures 26′U.

The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. Although FIG. 3 illustrates two semiconductor nanostructures 26′L and two semiconductor nanostructures 26′U in each of the multilayer stacks 22′, it should be appreciated that the exact number of semiconductor nanostructures 26′L and 26′U is not limited in the multilayer stacks 22′. For example, each multilayer stack 22′ may be include between one to three of the semiconductor nanostructures 26′L and between one to three of the semiconductor nanostructures 26′U. In this way, each of the upper and lower nanostructure-FETs may have anywhere between one and three channel regions provided by the semiconductor nanostructures 26′U and 26′L, respectively. The middle semiconductor nanostructures 26'M are the semiconductor nanostructures 26′ that are immediately above/below (e.g., in contact with) the dummy nanostructures 24′B. The dummy nanostructures 24′B will be subsequently replaced with isolation structures. The isolation structures and the middle semiconductor nanostructures 26′M may define boundaries of the lower nanostructure-FETs and the upper nanostructure-FETs.

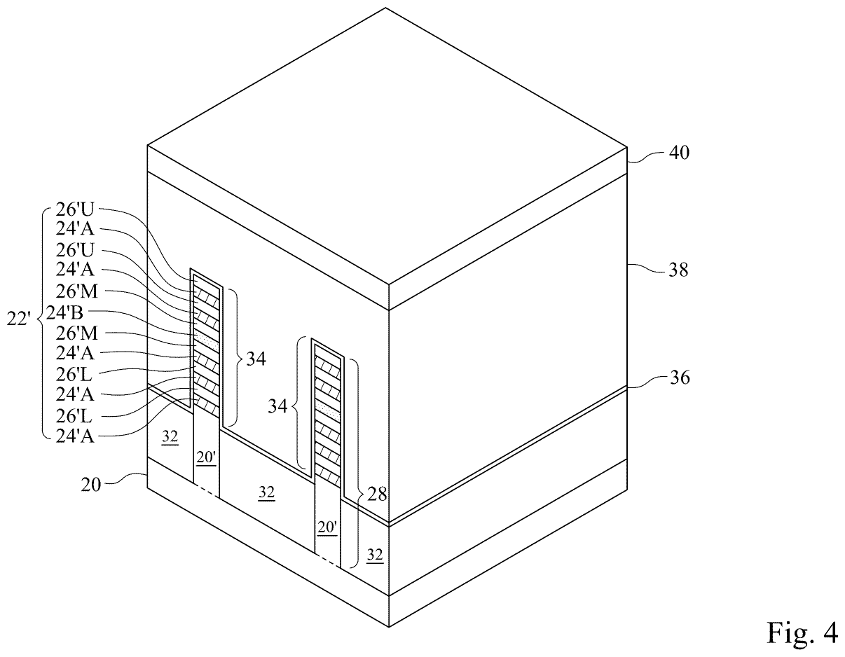

In FIG. 4, isolation regions 32 (also referred to as shallow trench isolation (STI) regions) are formed over the substrate 20 and between adjacent semiconductor strips 28. The respective process is illustrated as process 206 in the process flow 200 as shown in FIG. 18. Isolation regions 32 may include a dielectric liner and a dielectric material over the dielectric liner. Isolation regions 32 are then recessed. Some upper portions of semiconductor strips 28 (including multilayer stacks 22′) protrude higher than the remaining isolation regions 32 to form protruding fins 34.

Dummy dielectric layer 36 is then formed on the protruding fins 34. The respective process is illustrated as process 208 in the process flow 200 as shown in FIG. 18. Dummy dielectric layer 36 may be formed of or comprise, for example, silicon oxide, silicon nitride, a combination thereof, or the like, and may be deposited (and thus is formed on isolation regions 32) or thermally grown (thus will not be formed on isolation regions 32) according to acceptable techniques.

A dummy gate layer 38 is formed over the dummy dielectric layer 36. The respective process is illustrated as process 210 in the process flow 200 as shown in FIG. 18. The dummy gate layer 38 may be deposited, for example, through Physical Vapor Deposition (PVD), CVD, or other techniques, and then planarized, such as by a Chemical Mechanical Polish (CMP) process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

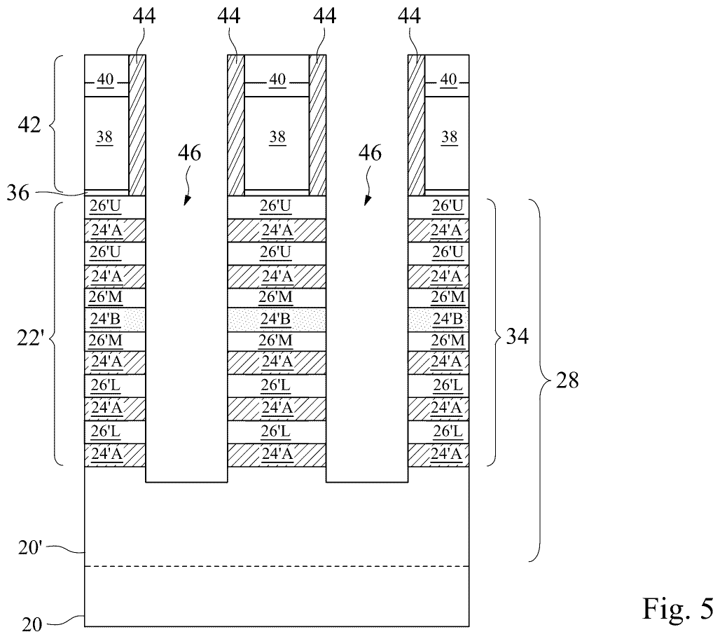

Next, the mask layer 40 may be patterned through photolithography and etching processes to form a mask, which is then used to etch and pattern dummy gate layer 38, and possibly dummy dielectric layer 36 to form dummy gate stacks 42. The respective process is illustrated as process 212 in the process flow 200 as shown in FIG. 18. A resulting structure is shown in FIG. 5. The remaining portions of mask layer 40, dummy gate layer 38, and dummy dielectric layer 36 form dummy gate stacks 42. The multilayer stack 22′ may include any number of the dummy semiconductor layers 24′A and semiconductor layers 26′U and 26′L.

In FIG. 5, gate spacers 44 are formed over the multilayer stacks 22′ and on the sidewalls of dummy gate stacks 42. The respective process is illustrated as process 214 in the process flow 200 as shown in FIG. 18. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Further referring to FIG. 5, source/drain recesses 46 are formed in semiconductor strips 28. The respective process is illustrated as process 216 in the process flow 200 as shown in FIG. 18. The source/drain recesses 46 are formed through etching, and may extend through the multilayer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes.

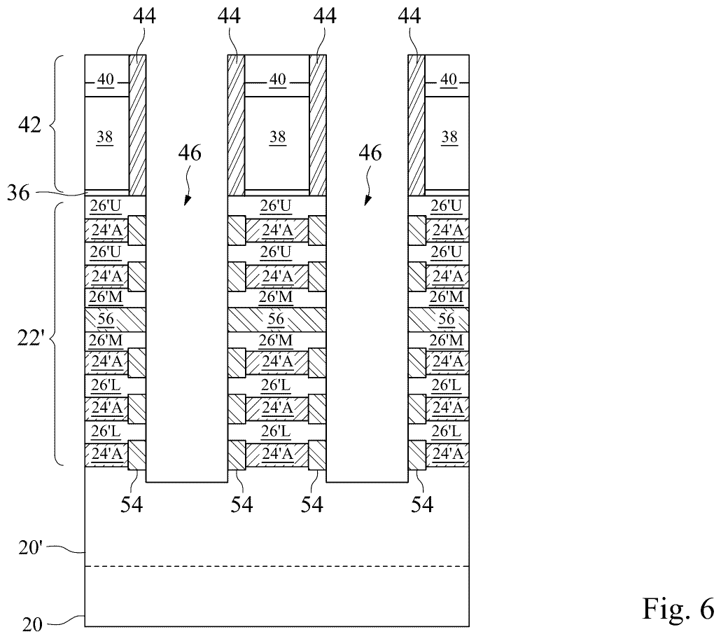

Referring to FIG. 6, inner spacers 54 and dielectric isolation layers 56 are formed. The respective process is illustrated as process 218 in the process flow 200 as shown in FIG. 18. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B.

The inner spacers 54 and the dielectric isolation layers 56 may be formed by conformally depositing an insulating material through the source/drain recesses 46, on sidewalls of the dummy nanostructures 56A, and between the upper and lower semiconductor nanostructures 26U and 26L, and then etching the insulating material. The insulating material may be a non-low-k dielectric material, which may be a carbon-containing dielectric material such as silicon oxycarbonitride, silicon oxycarbide, silicon oxynitride, or the like.

Middle semiconductor nanostructures 26′M and the dielectric isolation layers 56 may define the boundaries of the lower nanostructure-FETs and the upper nanostructure-FETs.

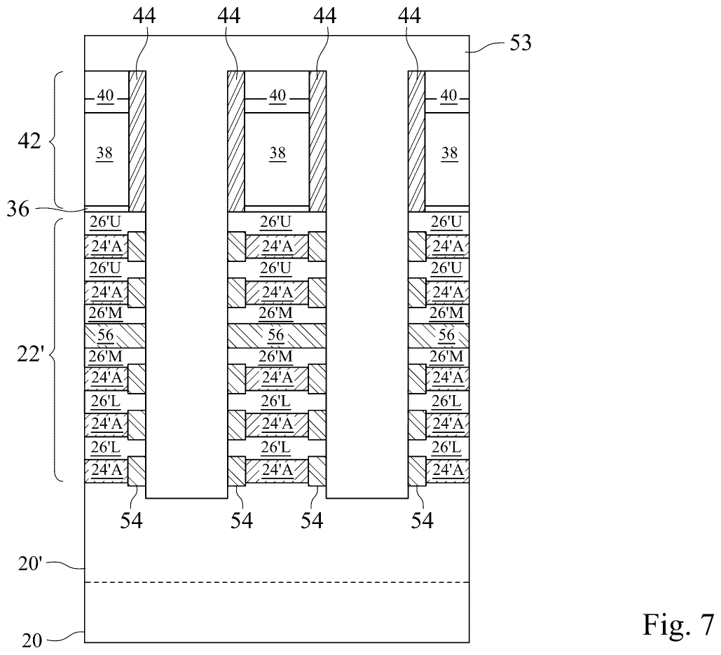

Referring to FIG. 7, sacrificial region 53 is deposited. The respective process is illustrated as process 220 in the process flow 200 as shown in FIG. 18. In accordance with some embodiments, the formation process includes depositing a sacrificial material to a level higher than the top surfaces of hard masks 40 and gate spacers 44, and performing a planarization process such as a CMP process or a mechanical polish process to level the top surface of the sacrificial material. The remaining sacrificial material may also have a top surface higher than the top surfaces of hard masks 40 and gate spacers 44.

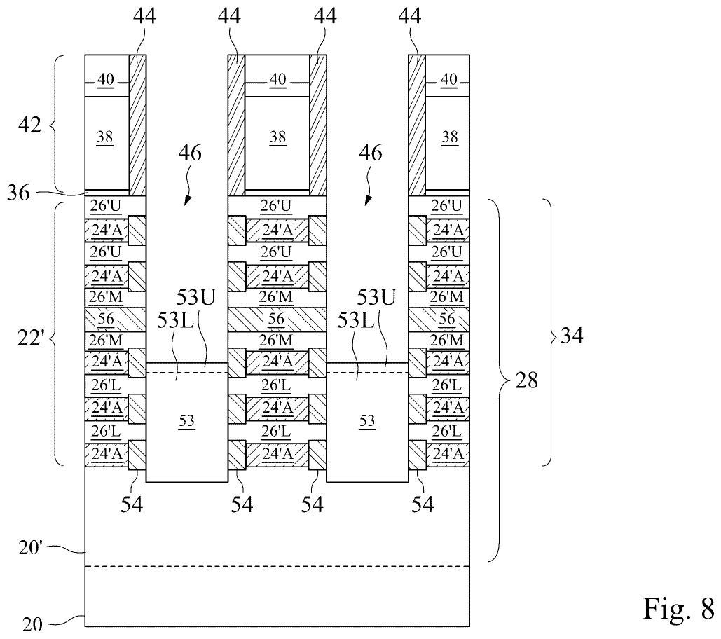

Next, as shown in FIG. 8, an etch back process may be performed to reduce the top surface of sacrificial regions 53, so that a plurality of sacrificial regions 53 are left at the bottoms of source/drain recesses 46. The respective process is illustrated as process 222 in the process flow 200 as shown in FIG. 18. The top surfaces of the sacrificial regions 53 are lower than dielectric isolation layer 56, and may be at a level between the top surface and the bottom surface of the inner spacer 54 that is immediately lower than dielectric isolation layer 56. The etch-back of sacrificial regions 53 may be performed using an etching gas selected from F₂, Cl₂, N₂, N₂H₂, HBr, HCl, or the like, or combinations thereof.

In accordance with alternative embodiments, instead of depositing, planarizing, and etching back sacrificial region(s) 53, the sacrificial regions 53 are deposited through a bottom-up depositing process and at the bottoms of source/drain recesses 46. Through this process, the manufacturing cost may be saved.

It is appreciated that since sacrificial regions 53 are free from liners, the formation processes related to the formation and the etching back of the otherwise formed liners of the sacrificial regions 53 are saved, and the manufacturing throughout is increased.

In accordance with some embodiments, sacrificial regions 53 are formed of carbon, which are in the form of elemental carbon atoms, and are not in the form of carbon compounds. Sacrificial regions 53 may comprise pure carbon or substantially pure carbon, for example, with a carbon atomic percentage being greater than 90 percent or 95 percent. Sacrificial regions 53 may also comprise amorphous carbon in accordance with some embodiments.

In accordance with some embodiments in which sacrificial regions 53 comprises elemental carbon, the deposition of sacrificial regions 53 may be performed through a CVD process, which may be performed with or without plasma. Accordingly, the deposition process may include thermal and/or plasma CVD processes. The precursor comprises a carbon-containing precursor, which may comprise CH₄, C₂H₆, C₂H₄, C₂H₂, C₃H₈, C₃H₆, C₃H₄, or the like, or combinations thereof. Wafer temperature during the deposition of sacrificial region(s) 53 may be in the range between about 200° C. and about 400° C.

In accordance with alternative embodiments, the sacrificial regions 53 may contain other materials, which may also be carbon-containing compounds such as SiOC. The deposition process may be performed through a CVD process, which may be performed with or without plasma. Accordingly, the deposition process may include thermal and/or plasma CVD processes. The precursors may comprise a carbon-containing precursor and a silicon-containing precursor. For example, the carbon-containing precursor may comprise CH₄, C₂H₆, C₂H₄, C₂H₂, C₃H₈, C₃H₆, C₃H₄, or the like, or combinations thereof. The silicon-containing precursor may comprise silane (SiH₄), disilane (Si₂H₆), or the like, or combination thereof.

The wafer temperature in the deposition process may be in the range between about 200° C. and about 4° C. The carbon atomic percentage in the sacrificial regions 53 may be in the range between about 1 percent and about 18 percent.

In accordance with some embodiments, the entireties of sacrificial region 53 may be formed of a homogenous material, and the entirety of sacrificial regions 53 may have a uniform composition, with all parts of the sacrificial regions 53 comprising the same element(s) with the same atomic percentages.

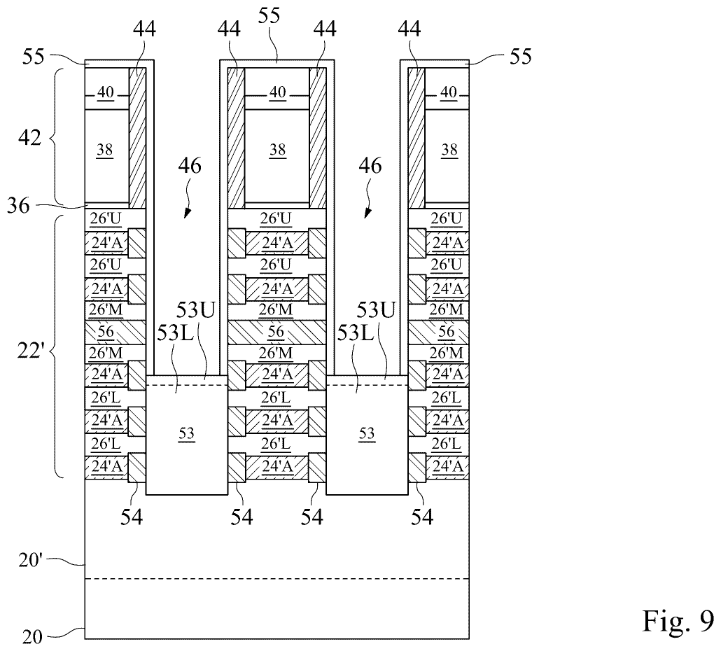

In accordance with some embodiments, as will be discussed in subsequent processes, sacrificial regions 53 have a graded composition. The top surface portions 53U of the sacrificial regions 53 preferably have a high carbon atomic percentage, so that the deposition of dielectric liners 55 (FIG. 9) is selective. The underlying portions 53L may have a lower carbon atomic percentage than the top surface portions 53U. For example, the atomic percentage of the top surface portions 53U may be greater than the atomic percentage of the lower portions 53L by a difference greater than 1 percent, 2 percent, 5 percent, 10 percent, or any value between 10 percent and 90 percent.

Referring to FIG. 9, a selective deposition process is performed to form dielectric liners 55, which are formed on the exposed surfaces of various features including hard masks 40, gate spacers 44, nanostructures 26'U, dielectric isolation layers 56, etc.. The respective process is illustrated as process 224 in the process flow 200 as shown in FIG. 18. The material of dielectric liners 55 is selected, so that the surfaces of hard masks 40, gate spacers 44, nanostructures 26′U, dielectric isolation layers 56, etc. are hydrophilic to the material of dielectric liners 55. On the other hand, the material of dielectric liners 55 is also selected so that the surfaces of sacrificial regions 53 are hydrophobic to the material of dielectric liners 55. In accordance with some embodiments in which sacrificial region 53 comprises elemental carbon or SiOC, dielectric liners 55 may comprise SiN, AlOₓ, TiN, or the like.

The deposition of dielectric liners 55 may be performed through a conformal deposition process such as ALD, CVD, or the like. Due to the hydrophobic surface, however, dielectric liners 55 do not have horizontal portions deposited on the top surfaces of sacrificial regions 53.

In accordance with some embodiments, to achieve the selective deposition, besides the selection of the materials of sacrificial regions 53 and dielectric liners 55, process conditions are also controlled. In accordance with some embodiments, the wafer temperature in the formation of dielectric liners 55 may be in the temperature range of about 200° C. and about 600° C. If the deposition is not selective enough, the selectivity may further be increased by reducing the wafer temperature, for example, to a low-temperature range of lower than about 400° C, and may be in the range between about 200° C. and about 400° C.

In addition, other process conditions may be adjusted to achieve the selective deposition. For example, the pressure in the deposition chamber may be increased, so that mean free paths of the precursors are reduced, and it is more difficult for the precursors to reach the bottom of source/drain regions 46.

It is appreciated that if dielectric liners 55 are deposited as conformal layers, an anisotropic etching process would have to be performed to remove the horizontal portions of the dielectric liners 55 on the top surfaces of sacrificial regions 53, so that the sacrificial regions 53 may be revealed. By making the formation of the dielectric liners 55 to be selective, the anisotropic etching process may be skipped.

It is appreciated that due to the skip of the anisotropic etching process, at the time when the top surfaces of sacrificial regions 53 are revealed, the dielectric liners 55 still comprise horizontal portions covering the top surfaces of hard masks 40 and gate spacers 44. Furthermore, the sidewall portions and the horizontal portions may have a same thickness or a substantially same thickness, for example, with a thickness difference smaller than about 20 percent or 10 percent.

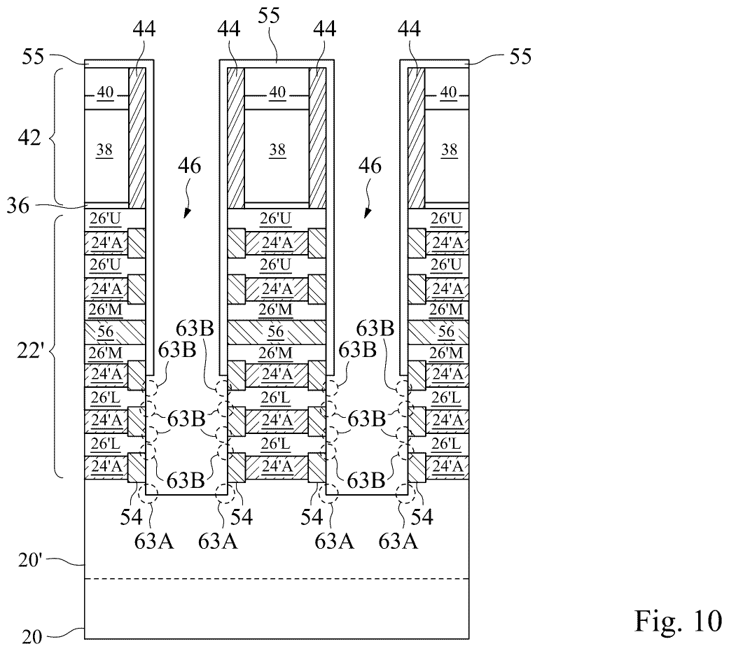

Sacrificial regions 53 are then removed through etching, and the resulting structure is shown in FIG. 10. The respective process is illustrated as process 226 in the process flow 200 as shown in FIG. 18. The sidewalls of nanostructures 26′L and inner spacers 54 are exposed. In accordance with some embodiments, the removal of sacrificial regions 53 may be performed through an ashing process, wherein a process gas selected from N₂, Cl₂, or the like, or the combination thereof may be used.

In accordance with some embodiments, after the removal of sacrificial regions 53, sacrificial regions 53 may have residue portions left in regions 63A, which are corner regions of source/drain recesses 46. In addition, when there are recesses at the joining regions 63B of inner spacers 54 and nanostructures 22B, there may also be residue portions of sacrificial regions 53 left in the recesses.

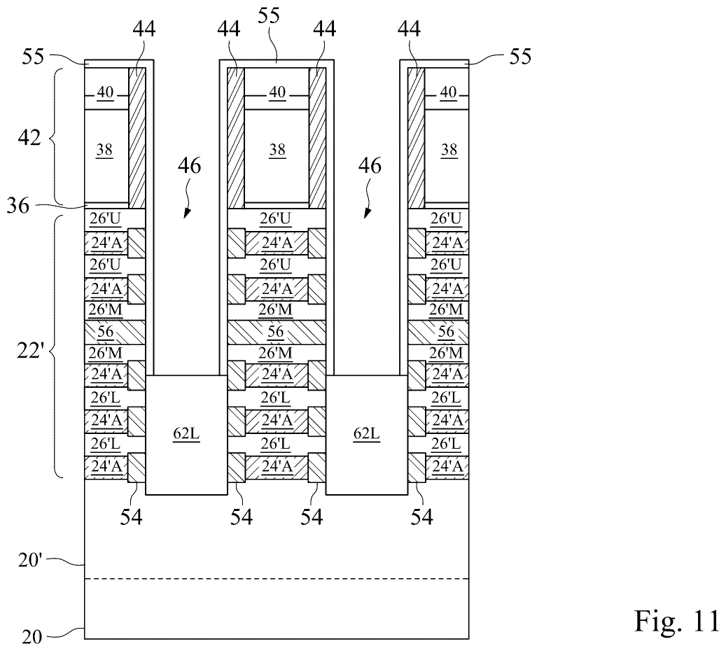

Next, as shown in FIG. 11, lower source/drain regions 62L are formed in the lower portions of the source/drain recesses 46 through selective epitaxy. The respective process is illustrated as process 228 in the process flow 200 as shown in FIG. 18. The lower source/drain regions 62L are in contact with the lower semiconductor nanostructures 26′L and are not in contact with the upper semiconductor nanostructures 26′U. Inner spacers 54 electrically insulate the lower source/drain regions 62L from the dummy nanostructures 24′A, which will be replaced with replacement gates in subsequent processes.

The lower (epitaxial) source/drain regions 62L have a conductivity type that is suitable for the device type (p-type or n-type) of the lower nanostructure-FET. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants.

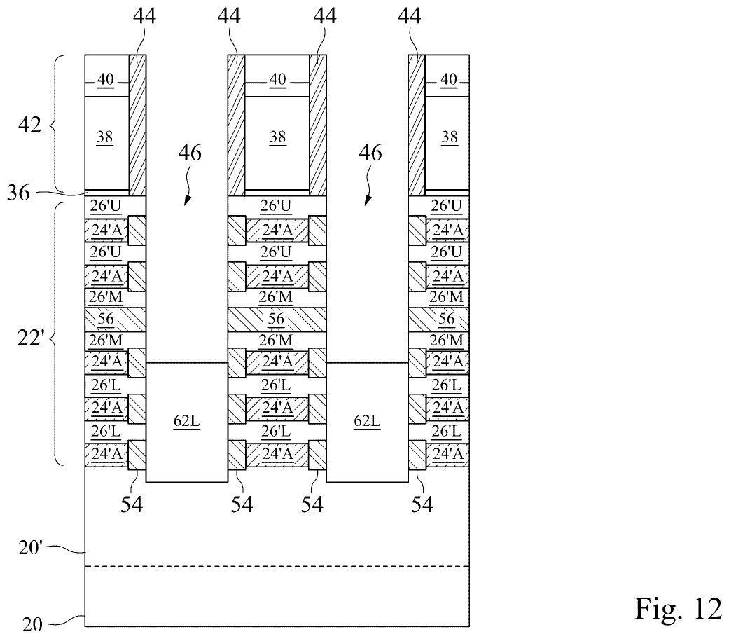

After the formation of lower source/drain regions 62L, dielectric liners 55 are removed in an etching process. The respective process is illustrated as process 230 in the process flow 200 as shown in FIG. 18. The resulting structure is shown in FIG. 12. In accordance with some embodiments, the etching process may be performed through a wet etching process, and the etching chemical comprises the solution of NH₄OH and H₂O₂. The temperature of the etching chemical may be in the range between about 40° C. and about 60° C. After the etching process, nanostructures 26′U are exposed.

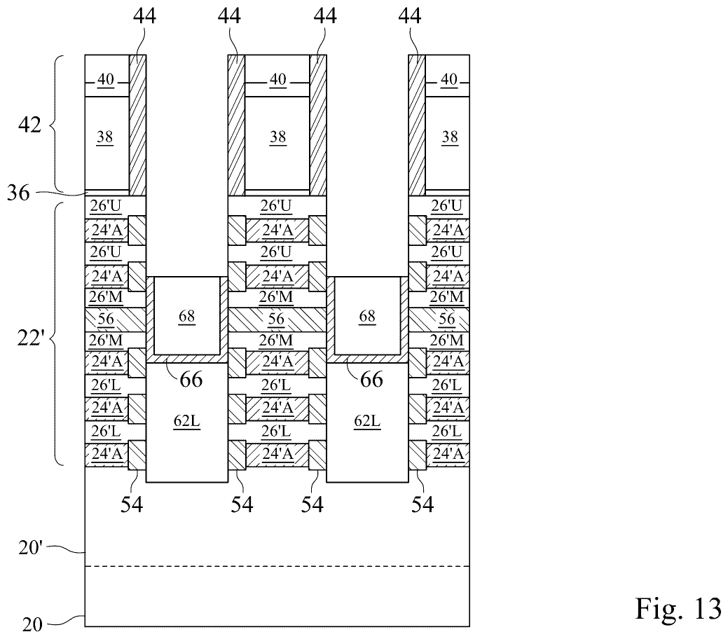

Referring to FIG. 13, a contact etch stop layer (CESL) 66 and an inter-layer dielectric (ILD) 68 are formed over lower source/drain regions 62L. The respective process is illustrated as process 232 in the process flow 200 as shown in FIG. 18. The CESL 66 may be formed of silicon nitride, silicon oxide, silicon oxynitride, or the like, which may be formed by any suitable deposition process, such as CVD, ALD, or the like.

ILD 68 is formed over CESL 66. ILD 68 may be formed of a dielectric material, which may be deposited by any suitable method, such as FCVD, plasma-enhanced CVD (PECVD), or CVD. The applicable dielectric material of the ILD 68 may include silicon oxide, phospho-silicate glass (PSG), boro-silicate glass (BSG), boron-doped phospho-silicate glass (BPSG), undoped silicate glass (USG), or the like.

The formation processes of ILD 68 and CESL 66 may include depositing a conformal CESL layer, depositing a material for ILD 68, and followed by a planarization process and then an etch-back process. An isotropic etching process is then performed to remove the portions of the CESL 66 higher than the recessed ILD 68. After the recessing, the sidewalls of the upper semiconductor nanostructures 26′U are exposed.

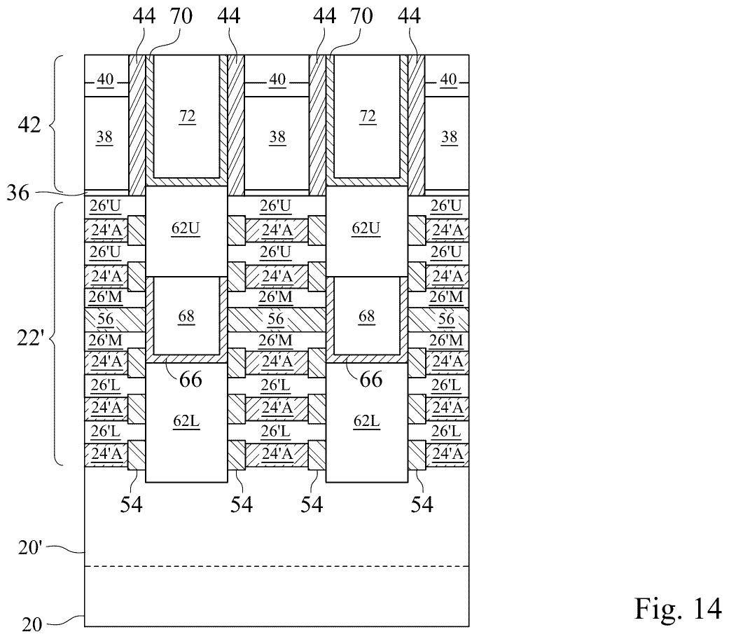

Referring to FIG. 14, upper source/drain regions 62U are formed in the upper portions of the source/drain recesses 46 through selective epitaxy. The respective process is illustrated as process 234 in the process flow 200 as shown in FIG. 18. The materials of upper source/drain regions 62U may be selected from the same candidate group of materials for forming lower source/drain regions 62L, depending on the desired conductivity type of upper source/drain regions 62U.

The conductivity type of the upper source/drain regions 62U may be opposite to the conductivity type of the lower source/drain regions 62L. Alternatively stated, the upper source/drain regions 62U may be oppositely doped from the lower source/drain regions 62L. The upper source/drain regions 62U may be in-situ doped, and/or may be implanted, with an n-type or p-type dopant.

Further referring to FIG. 14, CESL 70 and ILD 72 are formed. The respective process is illustrated as process 236 in the process flow 200 as shown in FIG. 18. CESL 70 may be deposited through a conformal deposition process. The material and the formation method of CESL 70 may be selected from the same groups of candidate materials and formation methods of CESLs 66.

After the formation of CESL 70, ILD 72 is formed. The ILD 72 may be formed of a dielectric material, which may be deposited by any suitable conformal or bottom-up method, such as ALD, CVD, PECVD, or FCVD. The applicable dielectric material of the ILD 72 may include SiOC, SiOCN, SiC, or the like.

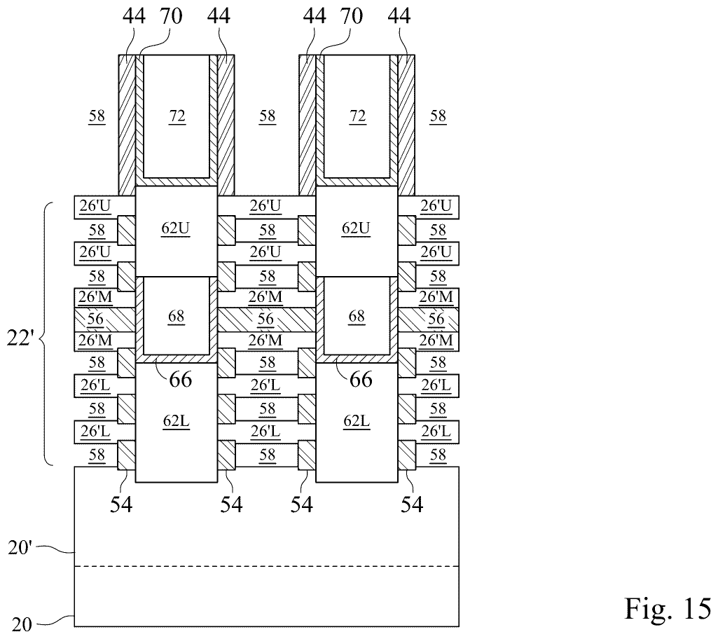

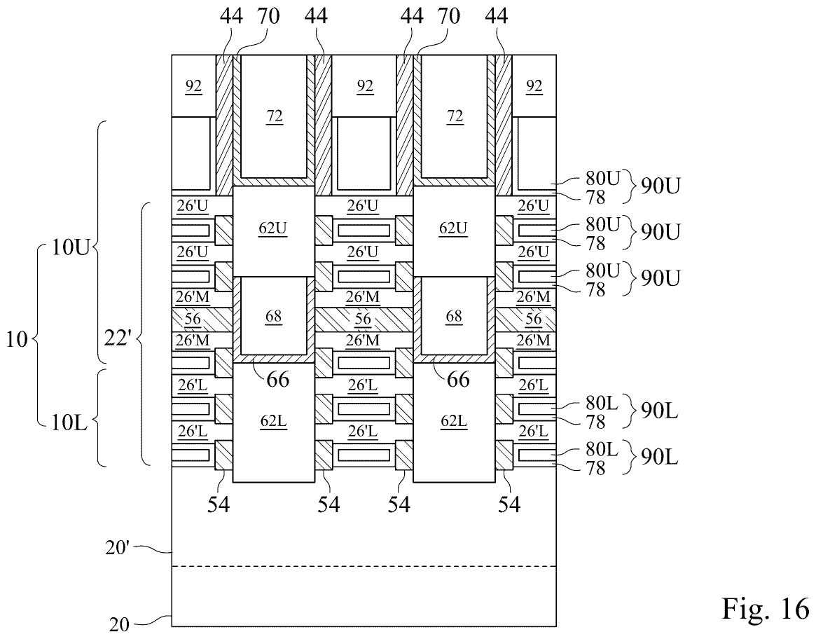

FIGS. 15 and 16 illustrate the formation of replacement gate stacks 90. The respective process is illustrated as process 238 in the process flow 200 as shown in FIG. 18. Referring to FIG. 15, the dummy gate stacks 42 (FIG. 14) are first removed in one or more etching processes, so that recesses 58 are formed. The remaining portions of the dummy nanostructures 24′A (FIG. 14) are then removed through etching, so that the recesses 58 extend between the semiconductor nanostructures 26′.

Referring to FIG. 16, gate dielectrics 78 are formed. The gate dielectrics 78 wrap around all (e.g., four) sides of the semiconductor nanostructures 26′. Each of the gate dielectrics 78 may include an interfacial layer, which may include an oxide such as silicon oxide. The interfacial layer may be formed through a thermal oxidation process, a chemical oxidation process, and/or a deposition process. The gate dielectrics 78 may also include high-k dielectric layers, which have a high dielectric constant (high-k) value greater than, for example, about 7.0. High-k dielectric layers may be formed of or comprise a metal oxide or a silicate of a metal selected from hafnium, zirconium, barium, titanium, lead, and combinations thereof.

Gate electrodes 80L and 80U are also formed. In the formation process, conductive layers are first formed on the high-k dielectric layer, and the remaining portions of the recesses are filled. Each of gate 80L and 80U may include a metal-containing material such as TiN, TaN, TiAl, TiAlC, cobalt, ruthenium, aluminum, tungsten, combinations thereof, and/or multilayers thereof. The gate electrodes 80L and 80U may provide work-functions suitable to the resulting lower FETs (lower transistors) 10L and upper FETs (upper transistors) 10U.

Gate dielectrics 78 and gate electrodes 80L collectively form gate stacks 90L. Gate dielectrics 78 and gate electrodes 80U collectively form gate stacks 90U. Self-aligned hard masks 92 may be formed over gate electrodes 80U. The Self-aligned hard masks 92 comprise a dielectric material, which may comprise SiN, for example. CFET 10, which includes upper FETs 10U and lower FETs 10L, is thus formed.

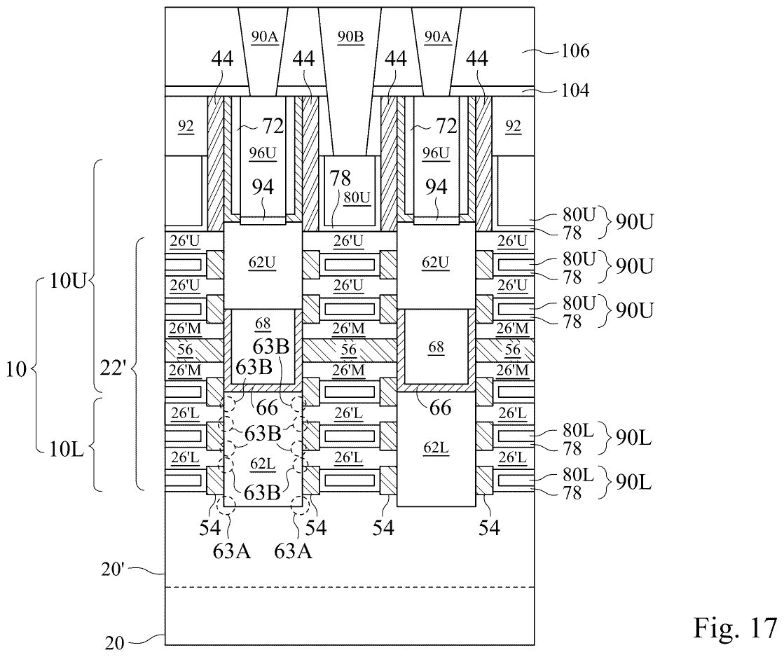

Referring to FIG. 17, source/drain silicide layers 94 are formed on the top surface of upper source/drain regions 62U. Source/drain contact plugs 96U are also formed. In addition, etch stop layer 104 and ILD 106 are formed. Source/drain contact plugs 90A and gate contact plug 90B are also formed.

In accordance with some embodiments, the residue portions of sacrificial regions 53 left in regions 63A and/or 63B (FIGS. 10 and 17) may be left in the final structure to cause the elements of the sacrificial regions 53 in regions 63A and/or 63B to be higher than the surrounding regions. For example, when sacrificial regions 53 comprises carbon, the carbon may be left at the corner regions of source/drain recesses 46. The carbon may also be diffused into regions 63A and 63B, which may be parts of semiconductor strips 20′, lower source/drain regions 62L, nanostructures 22B, and/or inner spacers 54. The carbon atomic percentage in regions 63A and 63B may be higher than the carbon atomic percentages in the regions surround the regions 63 by certain carbon atomic percentage differences, which may be greater than about 10 percent, and may be in the range between about 10 percent and about 90 percent. The carbon in regions 63 may comprise elemental carbon and/or carbon compound.

The embodiments of the present disclosure have some advantageous features. Sacrificial regions (which may be formed of a homogenous material or a graded material) are formed to define the boundaries of the lower source/drain regions. Also, a selective deposition process is performed to form a dielectric liner over the sacrificial regions. By adopting these processes and materials, fewer etching and patterning processes may be performed. The manufacturing throughput is thus improved, and the process variation is reduced.

In accordance with some embodiments of the present disclosure, a method comprises forming a multilayer stack comprising a first semiconductor nanostructure and a second semiconductor nanostructure over the first semiconductor nanostructure; forming a dummy gate stack over the multilayer stack; etching the multilayer stack to form a source/drain recess; forming a sacrificial region at a bottom of the source/drain recess; performing a selective deposition process to form a dielectric liner, wherein the dielectric liner is selectively deposited on a sidewall of the multilayer stack, and wherein a top surface of the sacrificial region is exposed to the source/drain recess; removing the sacrificial region; forming a lower source/drain region in the source/drain recess and electrically connected to the first semiconductor nanostructure; removing the dielectric liner to reveal the second semiconductor nanostructure; and forming an upper source/drain region to electrically connect to the second semiconductor nanostructure.

In an embodiment, the method further comprises forming a dielectric isolation region between the first semiconductor nanostructure and the second semiconductor nanostructure, wherein a topmost surface of the sacrificial region is lower than the dielectric isolation region. In an embodiment, the sacrificial region comprises carbon with a carbon atomic percentage being greater than about 1 percent. In an embodiment, the sacrificial region comprises silicon oxycarbide, and wherein the carbon atomic percentage of the sacrificial region is between about 1 percent and about 18 percent.

In an embodiment, the forming the sacrificial region comprises depositing elemental carbon. In an embodiment, the selective deposition process is performed at a temperature in a range between about 200° C. and about 400° C. In an embodiment, the dielectric liner is deposited as comprising a top portion overlapping the multilayer stack.

In an embodiment, at a time the top surface of the sacrificial region is exposed to the source/drain recess, the top portion of the dielectric liner that overlaps the multilayer stack remains. In an embodiment, an entirety of the sacrificial region comprises a homogenous material.

In accordance with some embodiments of the present disclosure, a method comprises forming a source/drain recess between two neighboring multilayer stacks, wherein a semiconductor region is underlying and exposed to the source/drain recess; forming a sacrificial region in the source/drain recess and contacting semiconductor layers of the two neighboring multilayer stacks; performing a deposition process to deposit a dielectric liner that comprises: horizontal portions overlapping the two neighboring multilayer stacks; and sidewall portions on sidewalls of the two neighboring multilayer stacks, wherein at a time during the deposition process, a top surface of the sacrificial region is exposed; removing the sacrificial region; and forming a lower source/drain region in a space left by the sacrificial region. In an embodiment, the method further comprises removing the dielectric liner.

In an embodiment, the dielectric liner is selectively deposited on exposed dielectric materials, with the top surface of the sacrificial region free from the dielectric liner deposited thereon. In an embodiment, the sacrificial region comprises carbon. In an embodiment, the forming the sacrificial region comprises depositing elemental carbon. In an embodiment, an entirety of the sacrificial region comprises a homogeneous material.

In an embodiment, the forming the sacrificial region comprises: depositing a lower portion having a first carbon atomic percentage; and depositing an upper portion over the lower portion, wherein the upper portion has a second carbon atomic percentage greater than the first carbon atomic percentage.

In accordance with some embodiments of the present disclosure, a method comprises forming a recess aside of a multilayer stack, wherein a sidewall of the multilayer stack is exposed to the recess; selectively depositing a dielectric liner on an upper portion of the sidewall, wherein a feature directly under the upper portion of the dielectric liner comprises a top surface underlying and exposed to the recess, and wherein the top surface is free from portions of the dielectric liner formed thereon; performing a selective epitaxy process to form a source/drain region filling a region lower than the dielectric liner; and removing the dielectric liner. In an embodiment, the method further comprises, before the selectively depositing the dielectric liner, forming a sacrificial region as the feature at a bottom of the recess; and after the dielectric liner is selectively deposited, removing the sacrificial region.

In an embodiment, the forming the sacrificial region comprises depositing carbon. In an embodiment, the forming the sacrificial region comprises depositing substantially pure carbon.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multilayer stack comprising a first semiconductor nanostructure and a second semiconductor nanostructure over the first semiconductor nanostructure;
forming a dummy gate stack over the multilayer stack;
etching the multilayer stack to form a source/drain recess;
forming a sacrificial region at a bottom of the source/drain recess;
performing a selective deposition process to form a dielectric liner, wherein the dielectric liner is selectively deposited on a sidewall of the multilayer stack, and wherein a top surface of the sacrificial region is exposed to the source/drain recess;
removing the sacrificial region;
forming a lower source/drain region in the source/drain recess and electrically connected to the first semiconductor nanostructure;
removing the dielectric liner to reveal the second semiconductor nanostructure; and
forming an upper source/drain region to electrically connect to the second semiconductor nanostructure.

2. The method of claim 1 further comprising:
forming a dielectric isolation region between the first semiconductor nanostructure and the second semiconductor nanostructure, wherein a topmost surface of the sacrificial region is lower than the dielectric isolation region.

3. The method of claim 1, wherein the sacrificial region comprises carbon with a carbon atomic percentage being greater than about 90 percent.

4. The method of claim 3, wherein the sacrificial region comprises silicon oxycarbide, and wherein the carbon atomic percentage of the sacrificial region is between about 1 percent and about 18 percent.

5. The method of claim 1, wherein the forming the sacrificial region comprises depositing elemental carbon.

6. The method of claim 1, wherein the selective deposition process is performed at a temperature in a range between about 200° C. and about 400° C.

7. The method of claim 1, wherein the dielectric liner is deposited as comprising a top portion overlapping the multilayer stack.

8. The method of claim 7, wherein at a time the top surface of the sacrificial region is exposed to the source/drain recess, the top portion of the dielectric liner that overlaps the multilayer stack remains.

9. The method of claim 1, wherein an entirety of the sacrificial region comprises a homogenous material.

10. A method comprising:
forming a source/drain recess between two neighboring multilayer stacks, wherein a semiconductor region is underlying and exposed to the source/drain recess;
forming a sacrificial region in the source/drain recess and contacting semiconductor layers of the two neighboring multilayer stacks;
performing a deposition process to deposit a dielectric liner that comprises:
horizontal portions overlapping the two neighboring multilayer stacks; and
sidewall portions on sidewalls of the two neighboring multilayer stacks, wherein at a time during the deposition process, a top surface of the sacrificial region is exposed;
removing the sacrificial region; and
forming a lower source/drain region in a space left by the sacrificial region.

11. The method of claim 10 further comprising removing the dielectric liner.

12. The method of claim 10, wherein the dielectric liner is selectively deposited on exposed dielectric materials, with the top surface of the sacrificial region free from the dielectric liner deposited thereon.

13. The method of claim 10, wherein the sacrificial region comprises carbon.

14. The method of claim 13, wherein the forming the sacrificial region comprises depositing elemental carbon.

15. The method of claim 10, wherein an entirety of the sacrificial region comprises a homogeneous material.

16. The method of claim 10, wherein the forming the sacrificial region comprises:
depositing a lower portion having a first carbon atomic percentage; and
depositing an upper portion over the lower portion, wherein the upper portion has a second carbon atomic percentage greater than the first carbon atomic percentage.

17. A method comprising:
forming a recess aside of a multilayer stack, wherein a sidewall of the multilayer stack is exposed to the recess;
selectively depositing a dielectric liner on an upper portion of the sidewall, wherein a feature directly under the upper portion of the dielectric liner comprises a top surface underlying and exposed to the recess, and wherein the top surface is free from portions of the dielectric liner formed thereon;
performing a selective epitaxy process to form a source/drain region filling a region lower than the dielectric liner; and
removing the dielectric liner.

18. The method of claim 17 further comprising:
before the selectively depositing the dielectric liner, forming a sacrificial region as the feature at a bottom of the recess; and
after the dielectric liner is selectively deposited, removing the sacrificial region.

19. The method of claim 18, wherein the forming the sacrificial region comprises depositing carbon.

20. The method of claim 19, wherein the forming the sacrificial region comprises depositing substantially pure carbon.
